(19) United States
(12) Patent Application Publication
(10) Pub. No.: US 2024/0113500 A1
(43) Pub. Date: Apr. 4, 2024

(54) SYSTEM AND METHOD FOR OPTICAL COUPLING

(71) Applicant: ROCKLEY PHOTONICS LIMITED, Altrincham (GB)

(72) Inventors: Babak BAHARI, Pasadena, CA (US); Abu THOMAS, Oak Park, CA (US); Andrea TRITA, Pasadena, CA (US); Aaron John ZILKIE, Pasadena, CA (US)

(21) Appl. No.: 18/477,483

(22) Filed: Sep. 28, 2023

Related U.S. Application Data
(60) Provisional application No. 63/377,693, filed on Sep. 29, 2022.

(51) Int. Cl. H01S 5/026; H01S 5/343

(52) U.S. Cl. CPC H01S 5/026; H01S 5/343

(57) ABSTRACT

A system and method for optical coupling. In some embodiments, the system includes a first semiconductor chip, including a semiconductor optical amplifier; and a second semiconductor chip, including a fork coupler. The fork coupler may includes a plurality of waveguide fingers, and an output waveguide. The waveguide fingers may be configured to guide, together, a first optical mode of the fork coupler; and the fork coupler may be arranged such that an output mode of the semiconductor optical amplifier couples to the first optical mode of the fork coupler.

### CROSS-REFERENCE TO RELATED APPLICATION(S)

The present application claims priority to and the benefit of U.S. Provisional Application No. 63/377,693, filed Sep. 29, 2022, entitled “FORK COUPLER”, the entire content of which is incorporated herein by reference.

### FIELD

One or more aspects of embodiments according to the present disclosure relate to optical systems, and more particularly to a system and method for optical coupling.

### BACKGROUND

Optical systems fabricated on semiconductor chips may include separate semiconductor chips for active optical components and for passive optical components.

It is with respect to this general technical environment that aspects of the present disclosure are related.

### SUMMARY

According to an embodiment of the present disclosure, there is provided a system, including: a first semiconductor chip, including a semiconductor optical amplifier; and a second semiconductor chip, including a fork coupler, wherein: the fork coupler includes: a plurality of waveguide fingers, and an output waveguide; the waveguide fingers are configured to guide, together, a first optical mode of the fork coupler; and the fork coupler is arranged such that an output mode of the semiconductor optical amplifier couples to the first optical mode of the fork coupler.

In some embodiments, the first semiconductor chip is a III-V semiconductor chip.

In some embodiments, the second semiconductor chip is a silicon nitride semiconductor chip.

In some embodiments, the first optical mode has a width between 1000 nm and 3000 nm.

In some embodiments, the system is configured to operate over a range of wavelengths, the range including a first wavelength, the first wavelength being greater than 200 nm and less than 1065 nm.

In some embodiments, the fork coupler includes 4 waveguide fingers.

In some embodiments, the fork coupler includes 5 waveguide fingers.

In some embodiments, the fork coupler does not include 8 waveguide fingers.

In some embodiments: an edge of the first semiconductor chip is separated from an edge of the second semiconductor chip by a gap; and a waveguide finger of the plurality of waveguide fingers is oblique to the gap.

In some embodiments, an angle between a waveguide finger of the plurality of waveguide fingers and a direction perpendicular to the gap is between 3 degrees and 25 degrees.

In some embodiments, the system further includes an index-matching material in the gap.

In some embodiments: the edge of the second semiconductor chip is an edge of a cavity in the second semiconductor chip, and the first semiconductor chip is in the cavity.

In some embodiments, the fork coupler further includes a waveguide-end bar; and each of the plurality of waveguide fingers extends to the waveguide-end bar.

In some embodiments, the system further includes a combiner between the output waveguide and the plurality of waveguide fingers.

In some embodiments, the combiner is a composite Y-coupler.

In some embodiments, the system further includes a waveguide section having a waist, between the output waveguide and the combiner.

In some embodiments, a width of the waveguide section at the waist is less than ½ of a width of the output waveguide.

In some embodiments, the first optical mode has a width at least 1.2 times as wide as a mode of the output waveguide.

In some embodiments, the first optical mode has a width at least 1.5 times as wide as a mode of the output waveguide.

### BRIEF DESCRIPTION OF THE DRAWINGS

These and other features and advantages of the present disclosure will be appreciated and understood with reference to the specification, claims, and appended drawings wherein:

FIG. 1 is a plan view of portions of two optical semiconductor chips, according to an embodiment of the present disclosure;

FIG. 2A is a plan view of portions of two optical semiconductor chips, according to an embodiment of the present disclosure;

FIG. 2B is a plan view of portions of two optical semiconductor chips, according to an embodiment of the present disclosure;

FIG. 3A is a plan view of a portion of an optical semiconductor chip, according to an embodiment of the present disclosure;

FIG. 3B is a plan view of a portion of an optical semiconductor chip, according to an embodiment of the present disclosure;

FIG. 4A is a graph of coupling loss, according to an embodiment of the present disclosure;

FIG. 4B is a graph of coupling loss, according to an embodiment of the present disclosure; and

FIG. 5 is a plan view of portions of two optical semiconductor chips, according to an embodiment of the present disclosure.

### DETAILED DESCRIPTION

The detailed description set forth below in connection with the appended drawings is intended as a description of exemplary embodiments of a system and method for optical coupling provided in accordance with the present disclosure and is not intended to represent the only forms in which the present disclosure may be constructed or utilized. The description sets forth the features of the present disclosure in connection with the illustrated embodiments. It is to be understood, however, that the same or equivalent functions and structures may be accomplished by different embodiments that are also intended to be encompassed within the scope of the disclosure. As denoted elsewhere herein, like element numbers are intended to indicate like elements or features.

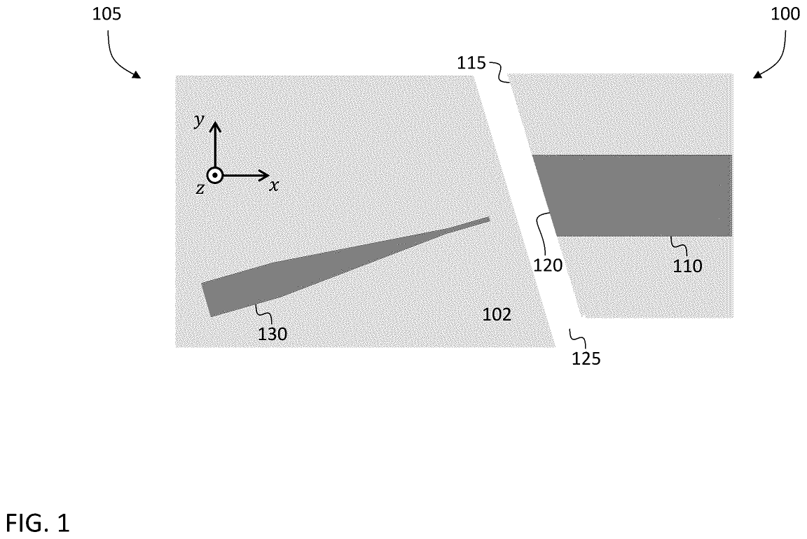

Waveguides are basic elements of optical systems that may carry light between different sections of a semiconductor chip (e.g., an optical semiconductor chip or a photonic integrated circuit (PIC)). Referring to FIG. 1, some such systems include multiple semiconductor chips, with, for example, a first semiconductor chip 100 including a first material (e.g., a III-V material, such as GaAs, AlGaAs, GaN or AlGaN) and a second semiconductor chip 105 including a second material (e.g., silicon nitride (e.g., Si₃N₄)). In such a combination of semiconductor chips, one semiconductor chip (e.g., the first semiconductor chip 100) may be an active semiconductor chip (e.g., a semiconductor chip including a semiconductor optical amplifier (SOA), e.g., a reflective semiconductor optical amplifier (RSOA) in a first waveguide 110) and the other semiconductor chip (e.g., the second semiconductor chip 105) may be a passive semiconductor chip, with, e.g., components such as filters or wavelength multiplexers (e.g., Bragg gratings, Mach-Zehnder interferometers, echelle gratings, or arrayed waveguide gratings).

Light may be coupled between the first semiconductor chip 100 and the second semiconductor chip 105; for example, light (e.g., laser light) may be generated on the first semiconductor chip 100, and coupled (or “transmitted”) to the second semiconductor chip 105 for processing (e.g., filtering), or the first semiconductor chip 100 may include a reflective semiconductor optical amplifier that together with a waveguide grating on the second semiconductor chip 105 forms a laser. For example, the first waveguide 110 on the first semiconductor chip 100 may extend to an edge 115 of the first semiconductor chip 100; at this edge, light may exit the first waveguide 110 at a facet 120 of the first waveguide 110 and be launched into a gap 125 between the first semiconductor chip 100 and the second semiconductor chip 105 (e.g., into a gap 125 between an edge of the first semiconductor chip 100 and an edge of the second semiconductor chip 105). This light may then be coupled into a second waveguide 130, on the second semiconductor chip 105.

The facet 120 of the reflective semiconductor optical amplifier may have an angle (i.e., the first waveguide 110 may be oblique to the gap 125 and to a direction normal (i.e., perpendicular) to the gap 125), which may be selected to reduce back-reflections into the reflective semiconductor optical amplifier. The reflective semiconductor optical amplifier may be electrically driven, and it may be fabricated as a ridge structure (which may define the first waveguide 110) patterned on top of a multiple quantum well (MQW) structure, with a width of 2 microns (μm). Both the first waveguide 110 and the second waveguide 130 may be single-mode waveguides.

The second waveguide 130, on the second semiconductor chip 105, may be connected to a taper (e.g., a tapered section of waveguide), as shown. The second waveguide 130 may have a height of 700 nm and a width of 400 nm. The width of 400 nm may be the width employed on most of the second semiconductor chip 105 (e.g., to guide light between optical components and to fabricate optical components (e.g., Mach Zehnder interferometers and the like)). In an embodiment in which the taper is absent, the second waveguide 130 extends to the gap, and the width of the second waveguide 130 at the gap 125 is 400 nm, the mode matching between the first waveguide 110 and the second waveguide 130 may be relatively poor, because the mode of the second waveguide 130 may be significantly smaller than that of the first waveguide 110. Moreover, in such an embodiment, the relatively small transverse size of the mode of the second waveguide 130 may result in relatively high beam divergence, in the gap 125, of the free-space beam corresponding to the mode of the second waveguide 130, resulting in high sensitivity of the coupling loss to transverse misalignments (misalignments caused by relative displacement of the first semiconductor chip 100 and the second semiconductor chip 105 in a direction for which the width of the gap 125 remains constant).

As such, the taper shown in FIG. 1 may cause the mode corresponding to the mode of the second waveguide 130 to be larger at the gap 125, such that at the gap 125 the mode of the second semiconductor chip 105 more nearly matches the mode of the first waveguide 110. This may result in reduced coupling loss, but in such an embodiment the coupling loss may be highly sensitive to fabrication variations (e.g., in the width of the narrow end of the taper) and to transverse misalignments.

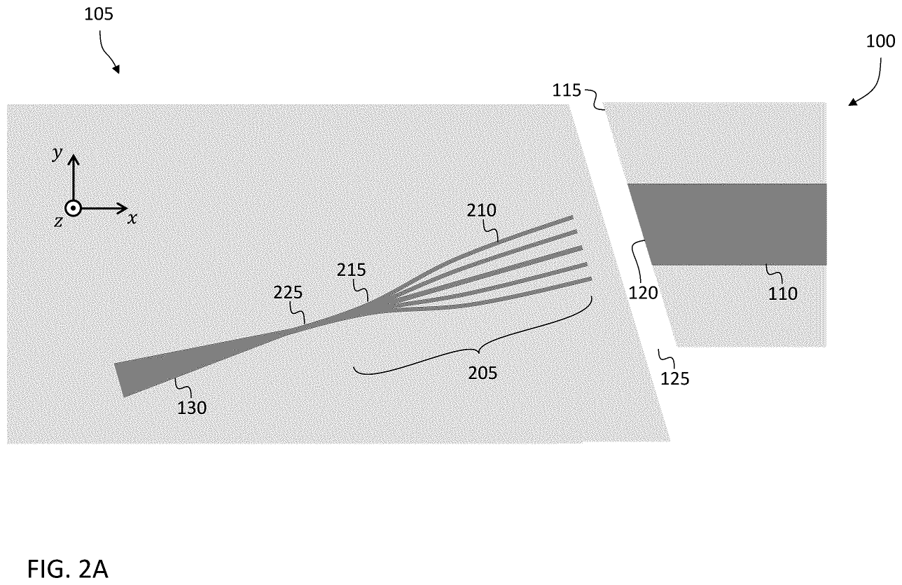

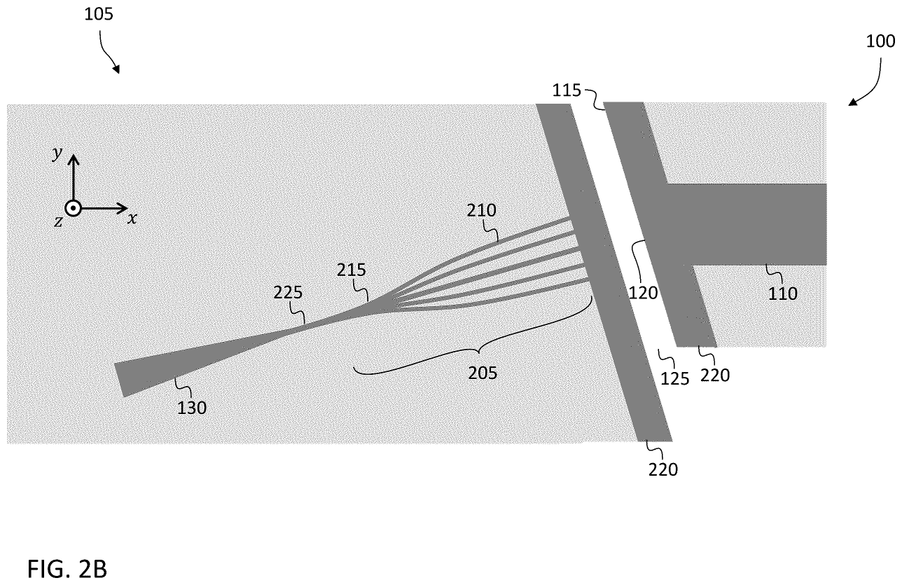

FIG. 2A is a plan view of the first semiconductor chip 100 and the second semiconductor chip 105, in some embodiments. As illustrated in FIG. 2A, the second waveguide 130 may be connected to a fork-shaped structure, which may be referred to as a fork coupler 205. In the embodiment of FIG. 2A, the fork coupler 205 has five waveguide fingers 210 that extend toward the edge of the second semiconductor chip 105, and that merge together at a combiner 215 (e.g., a 5-way combiner) to form the single waveguide which is connected to the second waveguide 130. The light from the first waveguide 110 may couple into a mode that is guided by all of waveguide fingers 210; as such, the five waveguide fingers 210 may be considered to form a single composite waveguide with five waveguide cores, each of the waveguide fingers 210 being one of the waveguide cores. In some embodiments, the size and shape of the mode guided by the composite waveguide (including the five waveguide fingers 210) is controllable by the number and dimensions of the waveguide fingers 210. Each of the waveguide fingers 210 may have a width between 50 nm and 500 nm, e.g., a width of 250 nm. In some embodiments, the composite waveguide has more or fewer than five waveguide fingers 210, e.g., it may have between two and 8 fingers. The mode guided by the composite waveguide may be wider (e.g., wider by factor between 1.1 and 5.0, e.g., by a factor of 1.2 or 1.5) than the mode guided by the second waveguide 130. The factor may be greater in a fork coupler configured to operate at a longer wavelength (e.g., at 1000 nm) than in a fork coupler configured to operate at a shorter wavelength (e.g., at 500 nm).

For purposes of this description, the waveguide fingers 210 may be numbered 1 through 5 from bottom to top in FIG. 2A. The combiner 215 may be a composite Y-coupler (as shown in FIG. 2A), which includes a straight through path (the third waveguide finger 210), a first, narrower Y-coupler (including the second and fourth waveguide fingers 210) and a second, wider Y-coupler (including the first and fifth waveguide fingers 210). Each of the waveguide fingers 210 may have a constant width (e.g., constant to within a number between 1% and 20%), the widths of the waveguide fingers 210 may all be equal (e.g., equal to within a number between 1% and 20%), and the spacing between any pair of adjacent waveguide fingers 210 may be uniform, at any point along the fork coupler 205 (e.g., uniform to within a number and between 1% and 20%). A waveguide section, between the second waveguide 130 and the combiner 215, may narrow to a waist 225, at which the waveguide may have a width of between 100 nm and 500 nm, e.g., a width of 250 nm. The waveguide structures on the second semiconductor chip 105 (e.g., the second waveguide 130, the waveguide section with the waist 225, the combiner 215, and the waveguide fingers 210) may be composed of silicon nitride (e.g., silicon nitride having a thickness of between 200 nm and 600 nm, e.g., 400 nm). These silicon nitride elements may be (i) on a layer of oxide (e.g., amorphous SiO₂) or (ii) on a thin slab (e.g., a slab having a thickness between 1 nm and 100 nm) of silicon nitride, which may be on a layer of oxide (e.g., amorphous SiO₂). The layer of oxide (e.g., amorphous SiO₂) may be on a layer of silicon, e.g., on a crystalline silicon substrate. The silicon nitride structures may be covered by a layer of oxide (e.g., amorphous SiO₂).

In some embodiments, one or both of (i) the first waveguide 110 and (ii) the waveguide fingers 210 may merge into a waveguide-end bar 220, a raised region (having a top surface flush with the top surface of the respective waveguide), as shown in FIG. 2B. Such a waveguide-end bar 220 may protect the end of the first waveguide 110 or the ends of the waveguide fingers 210 from damage during subsequent processing (after these structures are formed) and during assembly (the aligning and securing together of the first semiconductor chip 100 and of the second semiconductor chip 105). The two waveguide-end bars 220 may (if both present) have the same width, or they may have different widths, e.g., the waveguide-end bar 220 on the first semiconductor chip 100 may have a width of 1 micron, and the waveguide-end bar 220 on the second semiconductor chip 105 may have a width of 0.5 microns. An index-matching material (e.g., an index-matched fluid), may be present in (and may fill) the gap 125. The index-matching material may have an index of refraction that is (i) within 10% of the effective index of refraction of the composite waveguide, or (ii) within 10% of the effective index of refraction of the first waveguide 110, or (iii) between the effective index of refraction of the composite waveguide and the effective index of refraction of the first waveguide 110. The presence of this index-matching material may reduce the index of refraction contrast at the surface between the first waveguide 110 and the gap 125 and at the surfaces between the waveguide fingers 210 and the gap, and thereby reduce the effect of imperfections in these surfaces; as such, when an index-matching material is present, one or both of the waveguide-end bars 220 may be omitted. For example, if the index-matching material has an index of refraction close to that of the waveguide fingers 210, then defects in the end surfaces of the waveguide fingers 210 may have little effect. Omitting the waveguide-end bars 220 may make it possible to reduce the distance between the end of the first waveguide 110 and the ends of the waveguide fingers 210, and thereby to reduce the coupling loss.

In some embodiments, the first semiconductor chip 100 is flipped with respect to the second semiconductor chip 105 so that in a plan view of the top (active) surface of the second semiconductor chip 105, the bottom surface (e.g., the substrate) of the first semiconductor chip 100 is visible, or vice versa. In such a configuration the first semiconductor chip 100 and the second semiconductor chip 105 may be offset in the vertical direction so that the substrates are not aligned but the active surfaces are aligned. In some embodiments, the first semiconductor chip 100 is smaller (in a plan view) than the second semiconductor chip 105 and has a thinner substrate than the second semiconductor chip 105, and the first semiconductor chip 100 is in a cavity (e.g., bonded into a cavity) in the second semiconductor chip 105 (e.g., having been installed in the cavity using micro-transfer printing).

In some embodiments the transverse arrangement of the waveguide fingers 210 is non-uniform, e.g., the waveguide fingers 210 are spaced differently (e.g., more or less closely spaced), or have different widths (e.g., are wider or narrower), or both, near the center of the fork coupler 205 than at the edges (e.g., the third waveguide finger 210 may be wider than the first and fifth waveguide fingers 210), so that the effective index of refraction of the composite waveguide is different near the center than near the edges; this may affect the shape of the mode of the composite waveguide. For example, in some embodiments, one of the waveguide fingers 210 is wider, by an amount between 10% and 500%, than another one of the waveguide fingers 210, or the separation between one pair of adjacent waveguide fingers 210 is greater, by an amount between 10% and 500%, than the separation between another pair of adjacent waveguide fingers 210.

The direction of propagation within the fork coupler 205 and within the second waveguide 130 may be oblique to the gap 125 (and to a direction normal to the gap 125), with the angle between (i) the direction of propagation on the first semiconductor chip 100 and (ii) the direction normal to the gap 125 being related, for example, to the angle between (i) the direction of propagation on the second semiconductor chip 105 and (ii) the direction normal to the gap 125 by Snell's law, based on the effective index of refraction of the first waveguide 110 and the effective index of refraction of the end of the fork coupler 205, respectively. In some embodiments, the angle between the (i) the direction of propagation on the first semiconductor chip 100 and (ii) the direction normal to the gap 125 is between 1 degree and 20 degrees (e.g., it is 8 degrees) and the angle between the (i) the direction of propagation on the second semiconductor chip 105 and (ii) the direction normal to the gap 125 is between 1 degree and 30 degrees (e.g., it is 17 degrees).

A system such that of FIG. 2A or FIG. 2B may exhibit a coupling loss as low as 1 dB, and a bandwidth of 300 nm (or of at least 200 nm), at a center wavelength of 950 nm, where over the entire bandwidth the coupling loss is constant to within 0.5 dB. The back-reflection into the RSOA (e.g., into the first waveguide 110), may be less than 0.1%. The coupling loss may be constant to within 0.5 dB for lateral misalignments of up to 0.5 microns.

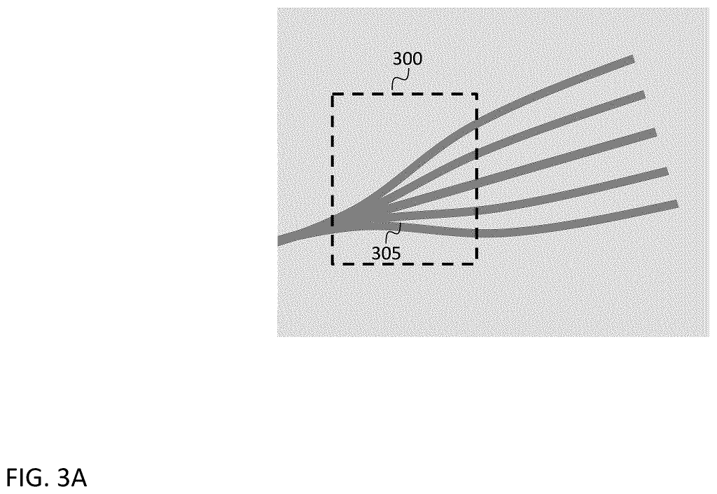

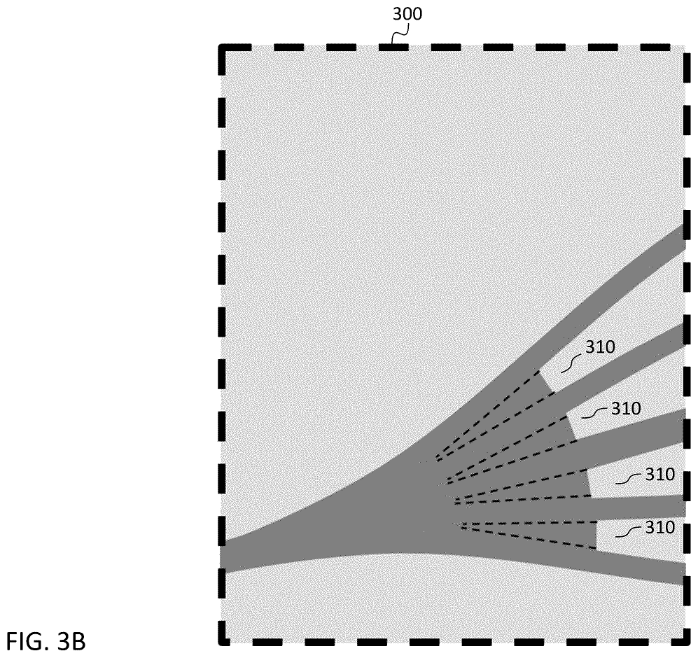

FIG. 3A shows the end of the fork coupler 205, in some embodiments. As illustrated, in a combiner region 300, all of the waveguide fingers 210 are connected to each other in a junction forming relatively sharp V-shaped gaps 305 between the waveguide fingers 210 where they meet. Such sharp features may be challenging to fabricate. As such, the points at which the waveguide fingers 210 meet may be fabricated instead with, as shown in FIG. 3B, rounded V-shaped gaps 310. The rounded ends of the gaps may each have a radius of about 200 nm, which may result in additional coupling loss of about 0.5 dB.

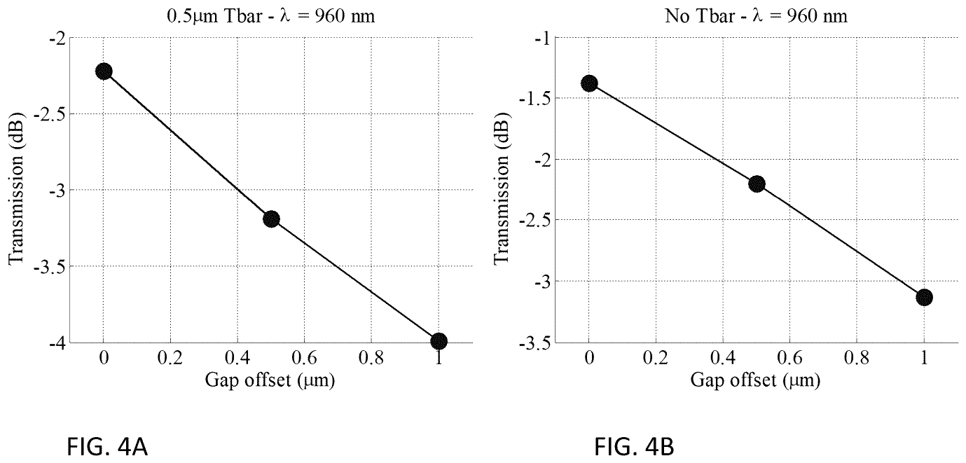

FIG. 4A shows the calculated effect of gap distance (or “gap offset”, i.e., the width of the gap 125) between the edge of the first semiconductor chip 100 and the corresponding edge of the second semiconductor chip 105, when there is a waveguide-end bar 220 on the second semiconductor chip 105. When the gap is zero, the coupling may be as high as −2.2 dB (i.e., the coupling loss may be as little as 2.2 dB). However, increasing the gap, e.g., to 1 μm, may cause an additional coupling loss of 1.8 dB. FIG. 4B shows the calculated coupling efficiency when there is no waveguide-end bar 220 on the second semiconductor chip 105. In this situation, the coupling efficiency may increase by about 0.8 dB compared to the coupling efficiency when a waveguide-end bar 220 is present on the second semiconductor chip 105.

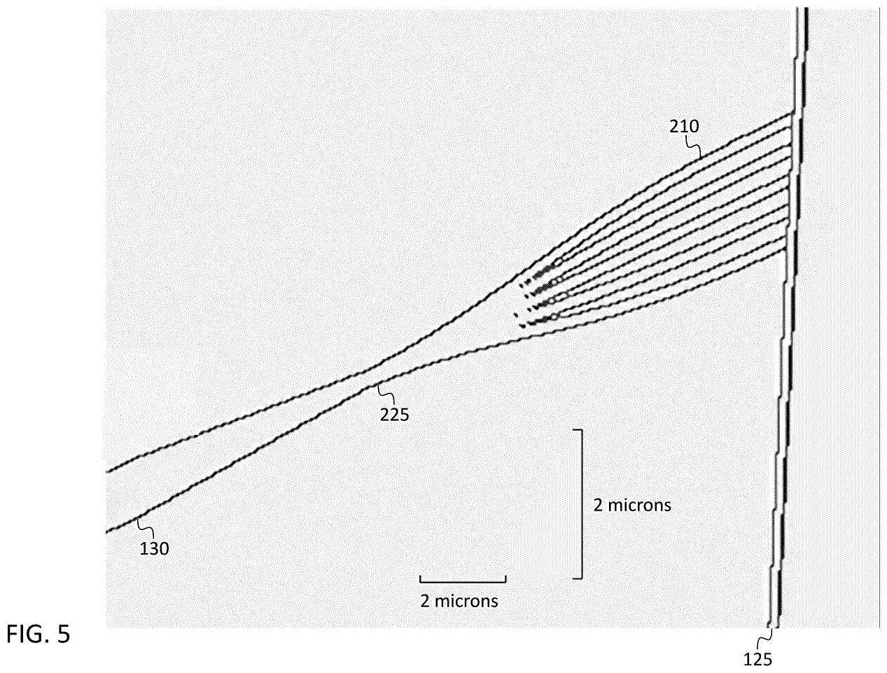

FIG. 5 is a plan view of the first semiconductor chip 100 and the second semiconductor chip 105 (the first waveguide 110 is not shown in FIG. 5). FIG. 5 is drawn to scale (with the vertical scale differing from the horizontal scale) in some embodiments. In some embodiments, (as mentioned above) the top surface of the second semiconductor chip 105 is covered with a layer of oxide (e.g., SiO2). In some embodiments, instead of the waveguide fingers 210 being parallel as they extend away from the gap 125, they may diverge (and, then at some distance from the gap, begin to converge again, to meet at the combiner 215, so as to form a composite waveguide that at the gap 125 is better able to couple to the diverging beam received from the first waveguide 110. For example, the waveguide fingers 210 may diverge (in the direction away from the gap 125) so that an angle between one of the waveguide fingers 210 and another one of the waveguide fingers 210 is between 1 degree and and 35 degrees.

In some embodiments, a fork coupler on the second semiconductor chip 105 may be used to couple to a slab waveguide on the first semiconductor chip 100, or to couple to an optical fiber, instead of being used to couple to a waveguide (e.g., a waveguide of a reflective semiconductor optical amplifier). As used herein, the “width” (of a waveguide on a semiconductor chip, or of a mode of such a waveguide) refers to a measurement made parallel to the surface of the semiconductor chip and perpendicular to the direction of propagation of light in the waveguide, and the “height” (of a waveguide on a semiconductor chip, or of a mode of such a waveguide) refers to a measurement made perpendicular to the surface of the semiconductor chip and perpendicular to the direction of propagation of light in the waveguide. The width and height of a waveguide may be measured between 3 dB points (points at which the irradiance (or flux density) is half of its maximum value).

As used herein, “a portion of” something means “at least some of” the thing, and as such may mean less than all of, or all of, the thing. As such, “a portion of” a thing includes the entire thing as a special case, i.e., the entire thing is an example of a portion of the thing. As used herein, when a second quantity is “within Y” of a first quantity X, it means that the second quantity is at least X−Y and the second quantity is at most X+Y. As used herein, when a second number is “within Y %” of a first number, it means that the second number is at least (1−Y/100) times the first number and the second number is at most (1+Y/100) times the first number. As used herein, the word “or” is inclusive, so that, for example, “A or B” means any one of (i) A, (ii) B, and (iii) A and B.

As used herein, when a method (e.g., an adjustment) or a first quantity (e.g., a first variable) is referred to as being “based on” a second quantity (e.g., a second variable) it means that the second quantity is an input to the method or influences the first quantity, e.g., the second quantity may be an input (e.g., the only input, or one of several inputs) to a function that calculates the first quantity, or the first quantity may be equal to the second quantity, or the first quantity may be the same as (e.g., stored at the same location or locations in memory as) the second quantity.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

As used herein, the term “major component” refers to a component that is present in a composition, polymer, or product in an amount greater than an amount of any other single component in the composition or product. In contrast, the term “primary component” refers to a component that makes up at least 50% by weight or more of the composition, polymer, or product. As used herein, the term “major portion”, when applied to a plurality of items, means at least half of the items. As used herein, any structure or layer that is described as being “made of” or “composed of” a substance should be understood (i) in some embodiments, to contain that substance as the primary component or (ii) in some embodiments, to contain that substance as the major component.

Any numerical range recited herein is intended to include all sub-ranges of the same numerical precision subsumed within the recited range. For example, a range of “1.0 to 10.0” or “between 1.0 and 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Similarly, a range described as “within 35% of 10” is intended to include all subranges between (and including) the recited minimum value of 6.5 (i.e., (1−35/100) times 10) and the recited maximum value of 13.5 (i.e., (1+35/100) times 10), that is, having a minimum value equal to or greater than 6.5 and a maximum value equal to or less than 13.5, such as, for example, 7.4 to 10.6. Any maximum numerical limitation recited herein is intended to include all lower numerical limitations subsumed therein and any minimum numerical limitation recited in this specification is intended to include all higher numerical limitations subsumed therein.

Although exemplary embodiments of a system and method for optical coupling have been specifically described and illustrated herein, many modifications and variations will be apparent to those skilled in the art. Accordingly, it is to be understood that a system and method for optical coupling constructed according to principles of this disclosure may be embodied other than as specifically described herein. The invention is also defined in the following claims, and equivalents thereof.

What is claimed is:

1. A system, comprising:
a first semiconductor chip, comprising a semiconductor optical amplifier; and
a second semiconductor chip, comprising a fork coupler,
wherein:
the fork coupler comprises:
a plurality of waveguide fingers, and
an output waveguide;
the waveguide fingers are configured to guide, together, a first optical mode of the fork coupler; and
the fork coupler is arranged such that an output mode of the semiconductor optical amplifier couples to the first optical mode of the fork coupler.

2. The system of claim 1, wherein the first semiconductor chip is a III-V semiconductor chip.

3. The system of claim 1, wherein the second semiconductor chip is a silicon nitride semiconductor chip.

4. The system of claim 1, wherein the first optical mode has a width between 1000 nm and 3000 nm.

5. The system of claim 1, wherein the system is configured to operate over a range of wavelengths, the range including a first wavelength, the first wavelength being greater than 200 nm and less than 1065 nm.

6. The system of claim 1, wherein the fork coupler includes 4 waveguide fingers.

7. The system of claim 6, wherein the fork coupler includes 5 waveguide fingers.

8. The system of claim 1, wherein the fork coupler does not include 8 waveguide fingers.

9. The system of claim 1, wherein:
an edge of the first semiconductor chip is separated from an edge of the second semiconductor chip by a gap; and
a waveguide finger of the plurality of waveguide fingers is oblique to the gap.

10. The system of claim 9, wherein an angle between a waveguide finger of the plurality of waveguide fingers and a direction perpendicular to the gap is between 3 degrees and 25 degrees.

11. The system of claim 9, further comprising an index-matching material in the gap.

12. The system of claim 9, wherein:
the edge of the second semiconductor chip is an edge of a cavity in the second semiconductor chip, and
the first semiconductor chip is in the cavity.

13. The system of claim 1, wherein the fork coupler further comprises a waveguide-end bar; and
each of the plurality of waveguide fingers extends to the waveguide-end bar.

14. The system of claim 1, further comprising a combiner between the output waveguide and the plurality of waveguide fingers.

15. The system of claim 14, wherein the combiner is a composite Y-coupler.

16. The system of claim 14, further comprising a waveguide section having a waist, between the output waveguide and the combiner.

17. The system of claim 16, wherein a width of the waveguide section at the waist is less than ½ of a width of the output waveguide.

18. The system of claim 1, wherein the first optical mode has a width at least 1.2 times as wide as a mode of the output waveguide.

19. The system of claim 18, wherein the first optical mode has a width at least 1.5 times as wide as a mode of the output waveguide.
